(19) United States
(12) Patent Application Publication
(10) Pub. No.: US 2007/0021932 A1
(43) Pub. Date: Jan. 25, 2007

(54) Serial data transmission method and system

(75) Inventors: Kuo-Rong Chen, Panchiao City (TW); Chun-Chung Lee, Taipei (TW); Cheng-Hung Huang, Kung Kuan (TW)

Correspondence Address: BACON & THOMAS, PLLC, 625 SLATERS LANE, FOURTH FLOOR, ALEXANDRIA, VA, 22314, US

(73) Assignee: Sin Etke Technology Co., Ltd., Taipei City (TW)

(21) Appl. No.: 11/341,370

(22) Filed: Jan. 30, 2006

(30) Foreign Application Priority Data
Jul. 21, 2005 (TW) 094124668

(51) Int. Cl. G01R 19/00

(52) U.S. Cl. 702/64

(57) ABSTRACT

A serial data transmission system practical for use in a high noise environment, for example, in a car to facilitate accurate transmission of serial data between two electronic apparatus and to improve the signal-to-noise ratio and to save system resources at the receiving connector is disclosed to have an additional control line set between the transmitting connector and the receiving connector for transmitting a control signal from the transmitting connector to the receiving connector during transmission of a serial data such that the receiving connector controls the time to receive data and the time to end the receiving action accurately by means of comparing the control signal to a predefined condition, preventing receiving of noises.

### BACKGROUND OF THE INVENTION

1. Field of the Invention

The present invention relates to a data transmission method and a data transmission system and more particularly, to a serial data transmission method and a serial data transmission system for the serial data transmission method.

2. Description of Related Art

In regular serial data transmission systems, either digital type or analog type, the receiving connector needs to repeatedly scan the transmission line to see any data being delivered through the transmission line. Therefore, the receiving connector spends a lot of time and system resources to detect what is received to be data or noises. More particularly under a high noise environment, for example, inside a car where magnetic waves are mixing, the receiving connector wastes much time and system resources in detection. When noises are strong, the change of transmission error will be high, thereby affecting data transmission quality and stability.

Therefore, it is desirable to provide a serial data transmission method and system that eliminates the aforesaid problem.

### SUMMARY OF THE INVENTION

The present invention has been accomplished under the circumstances in view. The invention provides a serial data transmission system, which comprises a transmitting apparatus, a receiving apparatus, a first transmission line, and a second transmission line. The transmitting apparatus comprises a transmitting connector adapted to transmit serial data to the receiving apparatus through the first transmission line and to simultaneously transmit a control signal to the receiving apparatus through the second transmission line. The receiving apparatus comprises a receiving connector adapted to receive the at least one serial data and the control signal from the transmitting connector of the transmitting apparatus. The first transmission line electrically connected between the transmitting connector of the transmitting apparatus and the receiving connector of the receiving apparatus for transmitting the at least one serial data from the transmitting connector of the transmitting apparatus to the receiving connector of the receiving apparatus. The second transmission line electrically connected between the transmitting connector of the transmitting apparatus and the receiving connector of the receiving apparatus for transmitting the control signal from the transmitting connector of the transmitting apparatus to the receiving connector of the receiving apparatus.

Wherein the receiving connector of the receiving apparatus detects a voltage change of the control signal on the second transmission line in conformity with a predefined first specific condition and starts to receive the at least one serial data from the transmitting connector of the transmitting apparatus through the first transmission line. The receiving connector of the receiving apparatus stops the action of receiving the at least one serial data from the first transmission line when another voltage change of the control signal on the second transmission line has been detected in conformity with a predefined second specific condition. Therefore, the receiving connector accurately controls the time point to start receiving serial data and the time point to end the receiving action, thereby preventing receiving of noises during the period between the start time point and the end time point, improving signal-to-noise ration and saving system resources.

The aforesaid first specific condition can be that the voltage of the control signal has been changed from a first voltage to a second voltage and continuously maintained at the second voltage for a first predefined period, or the voltage of the control signal has been surpassed above a predefined voltage value for more than a second predefined period, or the voltage change of the control signal satisfies a series code such as 01101, 10010, or ASCII code, or satisfies a specific waveform such as the sine wave of a specific frequency.

The invention further provides a serial data transmission method for enabling a receiving connector of a receiving apparatus to receive at least one serial data from a transmitting connector of the transmitting apparatus through the first transmission line, and also enabling the transmitting connector of the transmitting apparatus to transmit a control signal to the receiving connector of the receiving apparatus through the second transmission line. The serial data transmission method comprises the steps of: a step of enabling the receiving connector to scan the second transmission line to detect whether a voltage change of the control signal on the second transmission line is in conformity with a predefined first specific condition, and a step of enabling the receiving connector to receive the at least one serial data from the first transmission line when the voltage change of the control signal on the second transmission line has been detected in conformity with the predefined first specific condition.

The serial data transmission method further comprises a step of driving the receiving connector to stop the action of receiving the at least one serial data from the first transmission line when another voltage change of the control signal on the second transmission line has been detected in conformity with a predefined second specific condition.

### BRIEF DESCRIPTION OF THE DRAWINGS

FIG. 1a is a schematic drawing showing a serial data transmission system according to a first embodiment of the present invention.

FIG. 1b is a schematic drawing showing a serial data transmission system according to a second embodiment of the present invention.

FIG. 2 is a schematic drawing showing a signal according to the first embodiment of the present invention.

FIG. 3 is a flow chart of the first embodiment of the present invention.

FIG. 4 is a schematic drawing showing a signal according to a third embodiment of the present invention.

FIG. 5 is a schematic drawing showing a signal according to a fourth embodiment of the present invention.

FIG. 6 is a schematic drawing showing a signal according to a fifth embodiment of the present invention.

### DETAILED DESCRIPTION OF THE PREFERRED EMBODIMENT

FIG. 1a is a schematic drawing showing a serial data transmission system according to a first embodiment of the present invention. The system takes one way serial data transmission for example, particularly for a serious data transmission method in high signal-to-noise ration circumstances, such as in car or RS-232 of serious data transmission method in the laboratory. According to FIG. 1a, a serial data is transmitted from the transmitting connector A of the transmitting apparatus 100 to the receiving connector B of the receiving apparatus 101. The first transmission line 10 transmits the serial data, the second transmission line 13 transmits the control signal, and the ground line 12 provides the reference voltage zero.

FIG. 1b is a schematic drawing showing a serial data transmission system according to a second embodiment of the present invention. This embodiment is a bi-directional transmission RS-232 of serious data transmission system. The first transmission line 10′ and the second transmission line 13′ are respectively transmitted the serial data and the control signal from the series port of the first electronic device 102 to the series port of the second electronic device 103. The third transmission line 11′ and the fourth transmission line 14′ are respectively transmitted the serial data and the control signal from the series port of the second electronic device 103 to the series port of the first electronic device 104.

All of above transmission lines can modify in the form of ports to connect two different electronic devices, such as a main sever for car, a guard device, a display device, a GPS system, etc., for providing the correct transmission between two electronic devices.

To simplify explanation of the spirit and scope of the present invention, the following embodiments are described based on the one-way data transmission in FIG. 1a to explain the relation between the transmitting connector A and the receiving connector B. In actual practice, bi-directional transmission method is commonly used in most electronic devices. Although only the first embodiment shown in FIG. 1a is explained, a person skilled in the art can easily understand and apply the bi-directional transmission of the second embodiment shown in FIG. 1b. Therefore, no further detail description on the transmission process of the second embodiment is necessary.

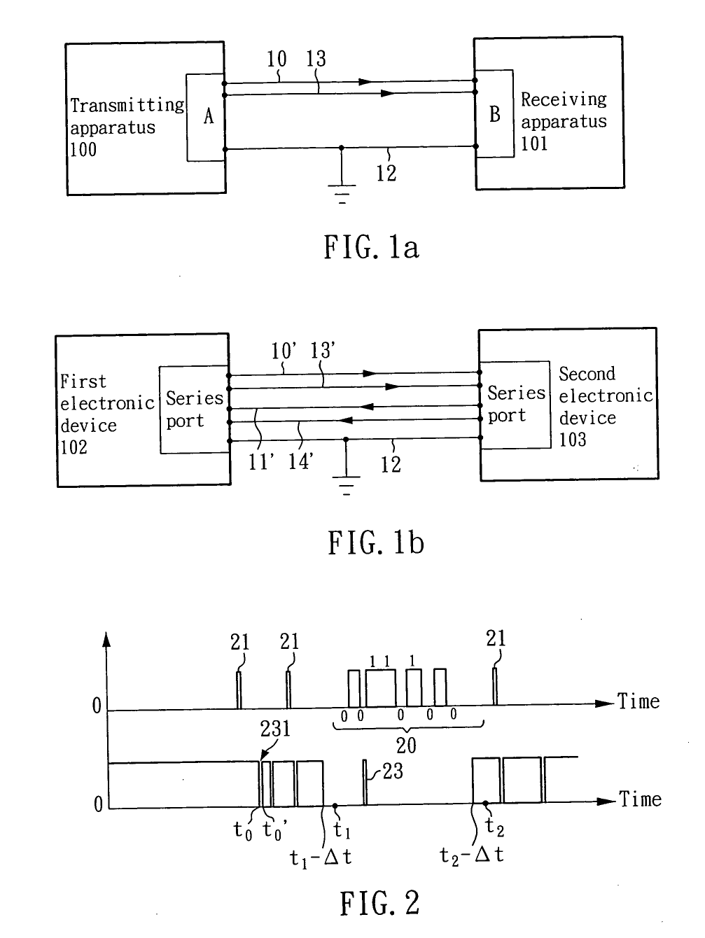

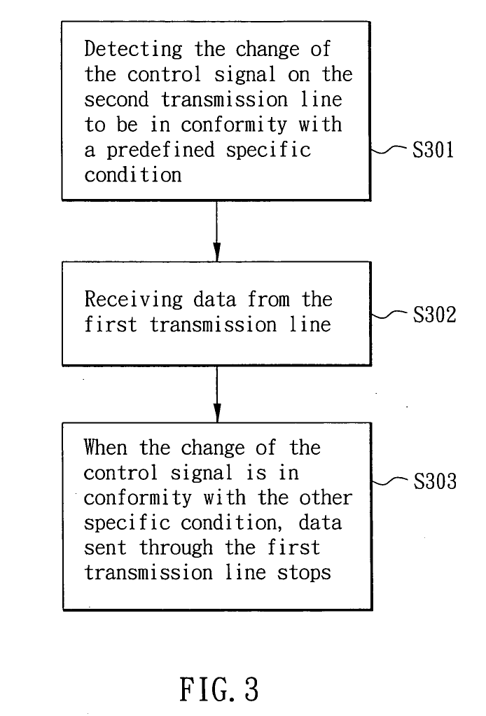

Please refer to FIGS. 1a, 2 and 3. FIG. 2 is a schematic drawing showing a signal according to the first embodiment of the present invention. FIG. 3 is a flow chart of the first embodiment of the present invention. In FIG. 2, the upper part shows the series data on the first transmission line 10 sent from the transmitting connector A of the transmitting apparatus 100; the lower part shows the control signal on the second transmission line 13 sent from the transmitting connector A. Noises 21 on the first transmission line 10 and noises 23 and 231 on the second transmission line 13 are produced due to surrounding interference during the transmission process.

According to this embodiment, the receiving connector B keeps detecting the control signal sent from the transmitting connector A through the second transmission line 13. When the change of the control signal is in conformity with one specific condition, namely, the first specific condition (Step S301), the receiving connector B starts to receive the serial data 20 being delivered through the first transmission line 10 in a proper order to finish an accurate data transmission (Step S302). Further, when the change of the control signal is in conformity with the other specific condition, namely, the second specific condition, the receiving connector B immediately stops receiving the serial data sent through the first transmission line 10 (Step S303).

Please refer to voltage change of the control signal on the second transmission line 13 as shown on the lower part in FIG. 2. Assume the first specific condition (i.e., the condition to start receiving data) according to this embodiment to be that the control signal has been changed from high voltage to low voltage and maintained at low voltage for a predefined period Δt=30 ms. The receiving connector B starts to count time when the voltage is changed from high to low at time point t0. However, the control signal changes from low voltage to high voltage at time point t0′ before counting to 30 ms. Therefore, the scanned result is not in conformity with the aforesaid first specific condition, and the receiving connector B does not care this voltage change that is caused by noises 231 and neglects any data sent through the fist transmission line 10. Similarly, the maintaining time of every voltage change caused by noises 231 before time point t1-Δt does not reach the preset period of 30 ms, therefore the receiving connector B need not receive any data transmitted through the first transmission line 10.

As shown on the lower part in FIG. 2, at time point t1-Δt, i.e., the transmitting connector A is going to transmit the serial data 20 through the first transmission line 10, at this time the transmitting connector A draws the control signal on the second transmission line 13 from high voltage to low voltage in advance, and holds the control signal at low voltage continuously for more than 30 ms. When the receiving connector B scanned this change to be in conformity with the condition that such voltage change has been held for more than Δt=30 ms, it regards the change to be in conformity with the aforesaid first specific condition and the serial data 20 transmitted through the first transmission line 10 to be effective data after time point t1.

Therefore, the receiving connector B neglects all noises 21 on the first transmission line 10 before start time point t1, and starts to receive serial data 20 transmitted after start time point t1. Therefore, this method effectively improves signal-to-noise ratio during transmission. Further, the receiving connector B need not receive all data from the first transmission line 10 uninterruptedly, or to waste system resources in verifying the effectiveness of all data transmitted through the first transmission line 10. Therefore, the invention can effectively save system resources at the receiving connector B.

When reached time point t2-Δt as shown on the lower part in FIG. 2, the control signal is changed from low voltage to high voltage and kept at high voltage for more than Δt=30 ms. At this time, the receiving connector B regards the change to be in conformity with the second specific condition (i.e., the condition to stop the receiving action), therefore the receiving connector B stops from receiving data from the first transmission line 10. Therefore, the receiving connector B needs not to receive noises 21 after end time point t2. In consequence, system resources at the receiving connector B are saved, and signal-to-noise ratio during transmission is greatly improved.

There are noises 23 on the second transmission line 13. However, because these noises 23 are not maintained at high voltage for more than 30 ms, the receiving connector B doesn't regard the presence of these noises to be in conformity with the second specific condition. Therefore, the receiving connector B doesn't stop the action of receiving data from the first transmission line 10.

The aforesaid first specific condition and second specific condition are pre-set in the system. The setting of these conditions is not limited to voltage switching or maintaining of the time period of 30 ms. These first and second specific conditions can be properly designed and arranged to fit different surrounding noises so as to improve the accuracy. Some other embodiments of the specific conditions are explained hereinafter.

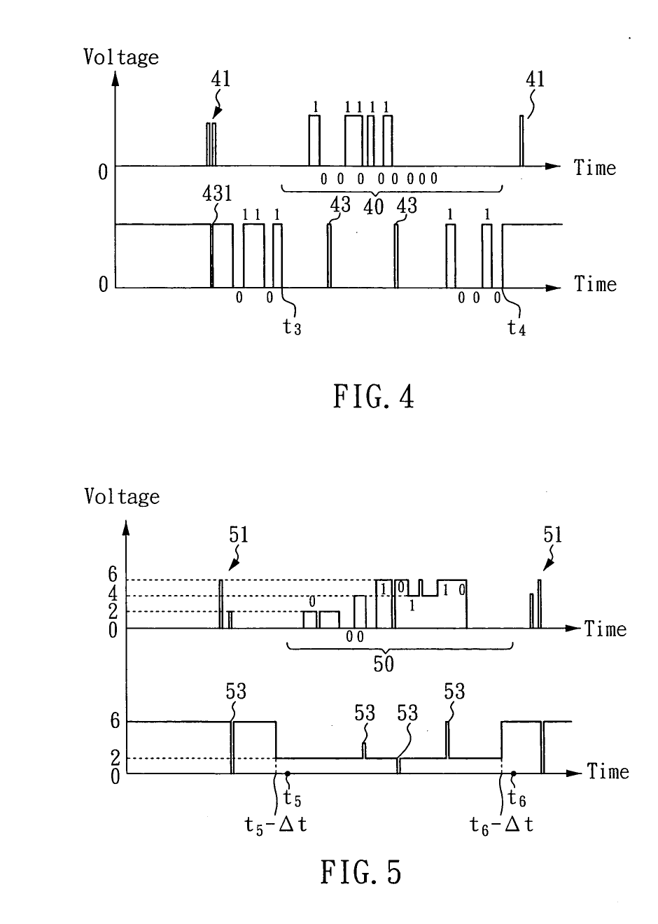

FIG. 4 shows a third embodiment of the present invention. This third embodiment changes the control signal on the second transmission line 13 to be the status on the lower part in FIG. 4. The upper part in FIG. 4 shows the data transmitted through the first transmission line 10. The lower part in FIG. 4 shows the control signal on the second transmission line 13. According to this embodiment, the control signal is a binary control signal. The system sets the start signal for the first specific condition to start receiving data as “01101”, and the end signal for the second specific condition to end the receiving action as “10010”. Therefore, the receiving connector B will only receive the serial data 40 transmitted through the first transmission line 10 within the time period from the start time point t3 till the end time point t4. The aforesaid start signal and end signal can both be set as “01101”.

According to this embodiment, there are many noises 43 and 431 on the second transmission line 13. However, these noises 43 and 431 will not affect the judgment of the specific condition “01101” or “10010” under the effect of good receiver means such as Matched Filter, Correlator, etc. Therefore, the time point t3 to start receiving data and the time point t4 to end the receiving action will be accurate, and the receiving connector B can accurately determine the data transmission start and end time points.

Similar to the aforesaid first embodiment, the receiving connector B will not receive the noises 41 on the first transmission line 10 before start time point t3 and after end time point t4. Therefore, this embodiment can also improve signal-to-noise ratio and save system resources.

FIG. 5 shows the fourth embodiment of the present invention. This embodiment changes the control signal on the second transmission line 13 to be the status shown on the lower part in FIG. 5. In FIG. 5, the upper part shows the data on the first transmission line 10, and the lower part shows the control signal on the second transmission line 13. With Gary Code, the bit “00” of the transmission data is encoded to be the first voltage (0V); the bit “01” of the transmission data is encoded to be the second voltage (2V); the bit “11” of the transmission data is encoded to be the third voltage (4V); the bit “10” of the transmission data is encoded to be the fourth voltage (6V).

According to this embodiment, the specific condition starts receiving data to set that the voltage has been switched from the fourth voltage (6V) to the second voltage (2V) and held at the second voltage (2V) for more than Δt=30 ms, and the second specific condition (i.e., the condition to end the receiving action) is set to be that the voltage has been switched from the second voltage (2V) to the fourth voltage (6V) and held at the fourth voltage (6V) for more than Δt=30 ms. Because there are four different voltages in this embodiment, the chance of switching the voltage from the fourth voltage to the second voltage due to interference of noises is relatively lower. In consequence, the chance of error in judgment is relatively reduced. As shown in FIG. 5, the receiving connector B can accurately find out the start time point t5 and the end point time t6 and accurately receive the serial data 50 transmitted through the first transmission line 10. Because the various noises 53 on the second transmission line 13 are not in conformity with the aforesaid specific conditions, they will not affect accurate receiving operation of the receiving connector B.

Similarly, there are many noises 51 on the first transmission line 10, however because these noises 51 are not within the time period between the start time point t5 and the end time point t6, they will not be received by the receiving connector B. Therefore, this embodiment also improves the signal-to-noise ratio and saves system resources.

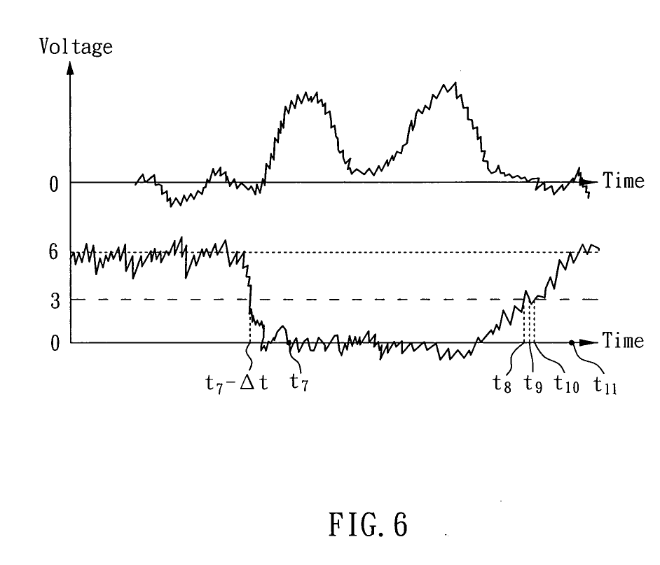

FIG. 6 shows the fifth embodiment of the present invention. This embodiment changes the control signal on the second transmission line 13 to be the status shown on the lower part in FIG. 6. In FIG. 6, the upper part shows the data on the first transmission line 10, and the lower part shows the control signal on the second transmission line 13. Unlike the aforesaid various embodiments, the signal according to this embodiment is an analog signal. According to this embodiment, the specific condition to start receiving data is set to be that the voltage value has been maintained below the average voltage value (3V) for more than Δt=30 ms, and the specific condition to end the receiving action is set to be that the voltage value has been maintained above the average voltage value (3V) for more than Δt=30 ms. If the control signal on the second transmission line 13 is stable, the receiving connector B can easily detect the start time point t7. If the control signal is unstable and the voltage of the control signal on the second transmission line 13 changes several times within a short period, for example, voltage changes at time point t8, time point t9 and time point t10, the means value of the voltages at these three time points is adopted for use in determining the end time point t11. This embodiment achieves the same effects as aforesaid embodiment.

Although the present invention has been explained in relation to its preferred embodiments, it is to be understood that many other possible modifications and variations can be made without departing from the spirit and scope of the invention as hereinafter claimed.

What is claimed is:

1. A serial data transmission method for enabling a receiving connector of a receiving apparatus to receive at least one serial data from a transmitting connector of a transmitting apparatus through a first transmission line, and also enabling the transmitting connector of said transmitting apparatus to transmit a control signal to the receiving connector of said receiving apparatus through a second transmission line; wherein, the serial data transmission method comprising the steps in series of:
a step of scanning said second transmission line to detect whether a voltage change of said control signal on said second transmission line is in conformity with a predefined first specific condition; and
a step of receiving said at least one serial data from said first transmission line when the voltage change of said control signal on said second transmission line has been detected in conformity with said predefined first specific condition.

2. The serial data transmission method as claimed in claim 1, wherein said predefined first specific condition is that the voltage of said control signal has been changed from a first voltage to a second voltage and continuously maintained at said second voltage for a first predefined period.

3. The serial data transmission method as claimed in claim 1, wherein said predefined first specific condition is that the voltage of said control signal has been dropped below a predefined voltage value for more than a second predefined period.

4. The serial data transmission method as claimed in claim 1, further comprising a step of stopping the action of receiving said at least one serial data from said first transmission line when another voltage change of said control signal on said second transmission line has been detected in conformity with a predefined second specific condition.

5. The serial data transmission method as claimed in claim 4, wherein said predefined second specific condition is that the voltage of said control signal has been changed from a second voltage to a first voltage and continuously maintained at said first voltage for a third predefined period.

6. The serial data transmission method as claimed in claim 4, wherein said predefined second specific condition is that the voltage of said control signal has been surpassed above a predefined voltage value for more than a fourth predefined period.

7. A serial data transmission system comprising:
a transmitting apparatus, said transmitting apparatus comprising a transmitting connector adapted to transmit a control signal and at least one serial data;
a receiving apparatus, said receiving apparatus comprising a receiving connector adapted to receive said control signal and said at least one serial data from said transmitting connector of said transmitting apparatus;
a first transmission line electrically connected between the transmitting connector of said transmitting apparatus and the receiving connector of said receiving apparatus for transmitting said at least one serial data from said transmitting connector of said transmitting apparatus to said receiving connector of said receiving apparatus; and
a second transmission line electrically connected between the transmitting connector of said transmitting apparatus and the receiving connector of said receiving apparatus for transmitting said control signal from said transmitting connector of said transmitting apparatus to said receiving connector of said receiving apparatus;
wherein said receiving connector of said receiving apparatus detects a voltage change of said control signal on said second transmission line in conformity with a predefined first specific condition and starts to receive said at least one serial data from said transmitting connector of said transmitting apparatus through said first transmission line.

8. The serial data transmission system as claimed in claim 7, wherein said predefined first specific condition is that the voltage of said control signal has been changed from a first voltage to a second voltage and continuously maintained at said second voltage for a first predefined period.

9. The serial data transmission system as claimed in claim 7, wherein said predefined first specific condition is that the voltage of said control signal has been surpassed above a predefined voltage value for more than a second predefined period.

10. The serial data transmission system as claimed in claim 7, wherein said receiving connector of said receiving apparatus stops the action of receiving said at least one serial data from said first transmission line when another voltage change of said control signal on said second transmission line has been detected in conformity with a predefined second specific condition.

11. The serial data transmission system as claimed in claim 10, wherein said predefined second specific condition is that the voltage of said control signal has been changed from a second voltage to a first voltage and continuously maintained at said first voltage for a third predefined period.

12. The serial data transmission system as claimed in claim 10, wherein said predefined second specific condition is that the voltage of said control signal has been surpassed above a predefined voltage value for more than a fourth predefined period.
